(19) United States
(12) Patent Application Publication
(10) Pub. No.: US 2014/0311581 A1
(43) Pub. Date: Oct. 23, 2014

(54) PRESSURE CONTROLLER CONFIGURATION FOR SEMICONDUCTOR PROCESSING APPLICATIONS

(71) Applicant: Applied Materials, Inc., Santa Clara, CA (US)

(72) Inventors: Sergey G. Belostotskiy, Santa Clara, CA (US); Andrew Nguyen, San Jose, CA (US); Jonathan Dinh, San Jose, CA (US); Ying-Sheng Lin, Fremont, CA (US)

(73) Assignee: Applied Materials, Inc., Santa Clara, CA (US)

(21) Appl. No.: 13/919,838

(22) Filed: Jun. 17, 2013

Related U.S. Application Data
(60) Provisional application No. 61/813,808, filed on Apr. 19, 2013.

(51) Int. Cl. H01L 21/67

(52) U.S. Cl. CPC H01L 21/67017
USPC 137/14; 137/565.11; 137/565.13

(57) ABSTRACT

An exemplary semiconductor processing system may include a processing chamber and a first pressure regulating device coupled with the processing chamber. A second pressure regulating device may also be coupled with the processing chamber separate from the first pressure regulating device. A first pump may be fluidly coupled with the first pressure regulating device and fluidly isolated from the second pressure regulating device. A second fluid pump may be fluidly coupled with the second pressure regulating device.

### CROSS-REFERENCES TO RELATED APPLICATIONS

This application claims the benefit of U.S. Provisional Application No. 61/813,808, filed Apr. 19, 2013, entitled “Pressure Controller Configuration for Semiconductor Processing Applications.” The entire disclosure of which is incorporated herein by reference for all purposes.

### TECHNICAL FIELD

The present technology relates to semiconductor processes and equipment. More specifically, the present technology relates to process chambers and components for system control.

### BACKGROUND

Integrated circuits are made possible by processes which produce intricately patterned material layers on substrate surfaces. Producing patterned material on a substrate requires controlled methods for deposition and removal of exposed material. For example, chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials, and each process may be performed in certain temperature and pressure regimes.

As these components and processes become more intricate, tighter tolerances may increasingly affect overall quality, and changes in environment may have an effect on the final product. For many semiconductor processes, a first process may be performed in one chamber followed by transfer to additional chambers for additional processes. Such transfer may produce unwanted defects due to environmental changes as well as increased queue times for the overall manufacturing.

Thus, there is a need for improved methods and systems for performing semiconductor fabrication processes. These and other needs are addressed by the present technology.

### SUMMARY

Systems and methods for controlling pressure in a semiconductor chamber are described. An exemplary semiconductor processing system may include a processing chamber and a first pressure regulating device coupled with the processing chamber. A second pressure regulating device may also be coupled with the processing chamber separate from the first pressure regulating device. A first pump may be fluidly coupled with the first pressure regulating device and fluidly isolated from the second pressure regulating device. A second fluid pump may be fluidly coupled with the second pressure regulating device.

The processing systems may further include at least one first pressure measuring device coupled with the processing chamber and configured to provide information to the first pressure regulating device. The system may also include at least one second pressure measuring device coupled with the processing chamber and configured to provide information to the second pressure regulating device. The first pressure regulating device may be configured to regulate the processing chamber pressure within a first pressure range, and the first pressure range may be at or below about 5 Torr, and may be at or below about 1 Torr. The second pressure regulating device may be configured to regulate the processing chamber pressure within a second pressure range, and the second pressure range may be at or above about 0.1 Torr, and may be at or above about 1 Torr. In disclosed embodiments, the second pressure regulating device may be configured to be closed when the first pressure regulating device is open. Additionally, the first pressure regulating device may be configured to be closed when the second pressure regulating device is open.

An exemplary semiconductor processing system according to the present technology may include a processing chamber and a first pressure regulating device coupled with the processing chamber along a first fluid line. The system may include a second pressure regulating device coupled with the processing chamber separately from the first pressure regulating device along a second fluid line. The system may further include a first pump fluidly coupled with the first pressure regulating device along the first fluid line, and may also include a second pump fluidly coupled with the second pressure regulating device. The second pump may also be fluidly coupled with the first pressure regulating device in disclosed embodiments. The second pump may also be fluidly coupled with a third fluid line fluidly coupled with both the first fluid line and the second fluid line. The semiconductor processing system may also include at least one first pressure measuring device coupled with the processing chamber and configured to provide information to the first pressure regulating device. The semiconductor processing system may include at least one second pressure measuring device coupled with the processing chamber and configured to provide information to the second pressure regulating device.

Methods of operating a semiconductor processing system may include operating a first fluid pump coupled with a semiconductor processing chamber with a first pressure regulating device to produce a processing chamber pressure within a first pressure range. The methods may include closing the first pressure regulating device, and may include operating a second fluid pump coupled with the semiconductor processing chamber with a second pressure regulating device. The methods may also include opening the second pressure regulating device to produce a processing chamber pressure within a second pressure range. The first pressure range may be at or above about 1 Torr, and the second pressure range may be at or below about 1 Torr in disclosed embodiments.

Methods of operating a semiconductor processing system according to the disclosed technology may include operating a first fluid pump coupled with a semiconductor processing chamber with a first pressure regulating device to produce a processing chamber pressure within a first pressure range. The methods may also include closing the first pressure regulating device, and may include flowing a fluid into the processing chamber. The methods may also include operating a second pressure regulating device coupled with the semiconductor processing chamber to regulate the processing chamber within a second pressure range. In an exemplary method, the first pressure range may be at or below about 1 Torr, and the second pressure range may be at or above about 1 Torr.

Such technology may provide numerous benefits over conventional techniques. For example, improved queue times may be achieved based on fewer substrate transfers to additional chambers and systems. Additionally, system costs may decrease because of the greater flexibility afforded by chambers capable of performing multiple operations. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing system.

FIG. 2 shows a schematic cross-sectional view of an exemplary processing chamber.

FIG. 3 shows a bottom plan view of an exemplary showerhead according to the disclosed technology.

FIG. 4 shows a plan view of an exemplary faceplate according to the disclosed technology.

FIG. 5 shows a simplified system schematic according to the disclosed technology.

FIG. 6 shows a method of operating a semiconductor processing system according to the disclosed technology.

FIG. 7 shows a method of operating a semiconductor processing system according to the disclosed technology.

Several of the Figures are included as schematics. It is to be understood that the Figures are for illustrative purposes, and are not to be considered of scale unless specifically stated to be as such.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

The present technology includes systems and components for semiconductor processing. As semiconductor processes are continually improved, operational characteristics may be incorporated directly into the chamber designs in which the processes are performed via specialized components. However, as device characteristics continue to decrease in scale, less tolerance may be afforded to the operational parameters during processing.

In order to provide fine-tune controlling for semiconductor processing, processing systems and chambers may be particularly produced for the specific processes to be performed within the chambers. Specialized devices of limited range that afford high control within the range may often be utilized in the chamber and system production. For example, many chambers may be configured to perform a process within a particular pressure regime, and as such utilize components sized for that particular range. Although the chambers and systems may increase overall device quality, system throughput may be reduced as multiple chambers may be needed for each manufacturing process. This may particularly be the case when subsequent process steps may be performed within disparate pressure regimes, as the specific chamber components may be selected to operate in one of the pressure regions, but may not be selected to operate in a second pressure region. The present systems and methods, however, allow processing steps to be performed with a high level of control at multiple pressure regimes, which may not only improve device quality, but reduce process queue times as well.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as for use with etching processes alone.

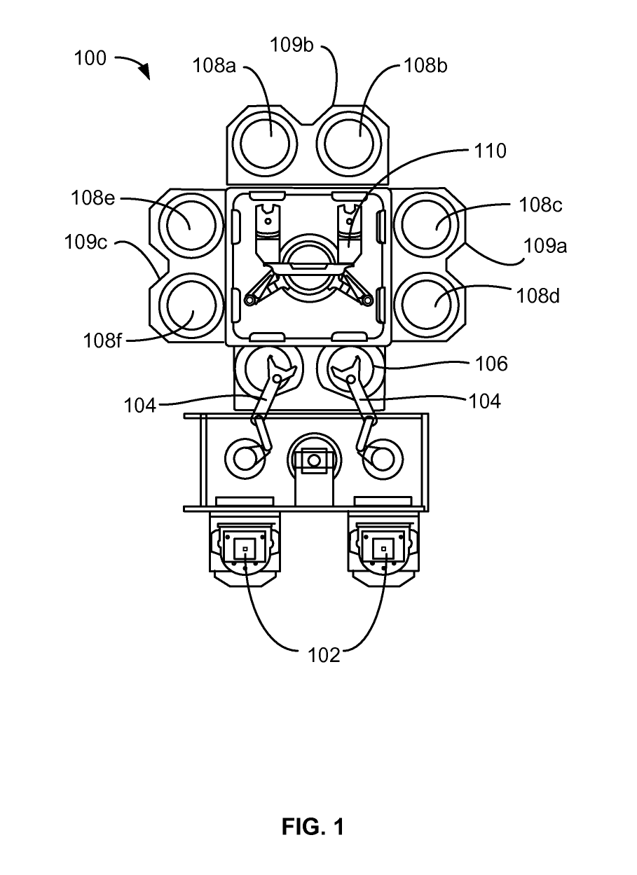

FIG. 1 shows a top plan view of one embodiment of a processing system 100 of deposition, etching, baking, and curing chambers according to disclosed embodiments. In the figure, a pair of front opening unified pods (FOUPs) 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the multi-step etch processes described herein in addition to cyclical layer deposition (CLD), atomic layer deposition (ALD), chemical vapor deposition (CVD), physical vapor deposition (PVD), etch, pre-clean, degas, orientation, and other substrate processes.

The substrate processing chambers 108a-f may include one or more system components for depositing, annealing, curing and/or etching a dielectric film on the substrate wafer. In one configuration, two pairs of the processing chamber, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to etch a dielectric film on the substrate. Any one or more of the processes described may be carried out in chamber(s) separated from the fabrication system shown in different embodiments. It will be appreciated that additional configurations of deposition, etching, annealing, and curing chambers for dielectric films are contemplated by system 100.

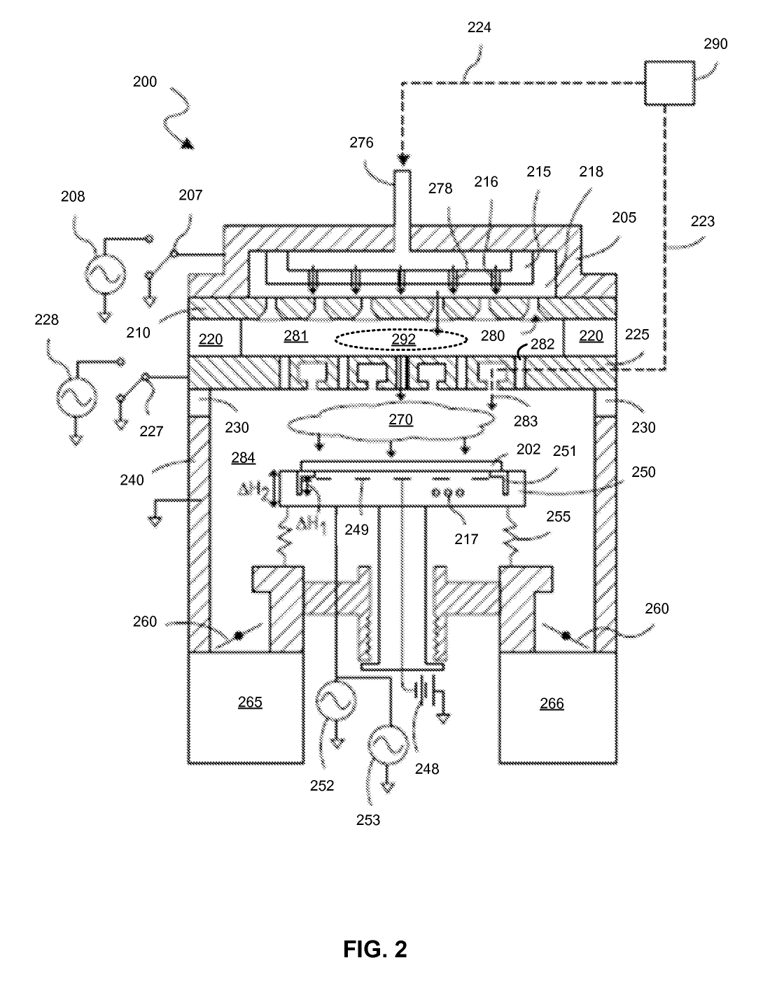

FIG. 2 shows a cross-sectional schematic of an exemplary processing chamber 200 according to the disclosed technology. Chamber 200 may be used, for example, in one or more of the processing chamber sections 108 of the system 100 previously discussed Generally, the etch chamber 200 may include a first capacitively-coupled plasma source to implement an ion milling operation and a second capacitively-coupled plasma source to implement an etching operation and to implement an optional deposition operation. The chamber 200 may include grounded chamber walls 240 surrounding a chuck 250. In embodiments, the chuck 250 may be an electrostatic chuck which clamps the substrate 202 to a top surface of the chuck 250 during processing, though other clamping mechanisms as would be known may also be utilized. The chuck 250 may include an embedded heat exchanger coil 217. In the exemplary embodiment, the heat exchanger coil 217 includes one or more heat transfer fluid channels through which heat transfer fluid, such as an ethylene glycol/water mix, may be passed to control the temperature of the chuck 250 and ultimately the temperature of the substrate 202. Chuck 250 may additionally include an embedded heater or heating elements configured to further affect and control wafer temperatures.

The chuck 250 may include a mesh 249 coupled to a high voltage DC supply 248 so that the mesh 249 may carry a DC bias potential to implement the electrostatic clamping of the substrate 202. The chuck 250 may be coupled to a first RF power source and in one such embodiment, so that both the DC voltage offset and the RF voltage potentials are coupled across a thin dielectric layer on the top surface of the chuck 250. In the illustrative embodiment, the first RF power source may include a first and second RF generator 252, 253. The RF generators 252, 253 may operate at any industrial frequency known in the art, however in the exemplary embodiment the RF generator 252 may operate at 13.56 MHz to induce a bias, which may provide advantageous ion directionality. Where a second RF generator 253 is also provided, the exemplary frequency may be 60 MHz.

With the chuck 250 to be RF powered, an RF return path may be provided by a first showerhead 225. The first showerhead 225 may be disposed above the chuck to distribute a first feed gas into a first chamber region 284 defined by the first showerhead 225 and the chamber wall 240. As such, the chuck 250 and the first showerhead 225 form a first RF coupled electrode pair to capacitively energize a first plasma 270 of a first feed gas within a first chamber region 284. A DC plasma bias, or RF bias, resulting from capacitive coupling of the RF powered chuck may generate an ion flux from the first plasma 270 to the substrate 202, e.g., Ar ions where the first feed gas is Ar, to provide an ion milling plasma. The first showerhead 225 may be grounded or alternately coupled to an RF source 228 having one or more generators operable at a variety of frequencies including, e.g., 40 MHz or 60 MH. In the illustrated embodiment the first showerhead 225 may be selectably coupled to ground or the RF source 228 through the relay 227 which may be automatically controlled during the etch process, for example by a controller (not shown).

As further illustrated in the figure, the etch chamber 200 may include a pump stack capable of high throughput at low process pressures. In embodiments, at least one turbo molecular pump 265, 266 may be coupled with the first chamber region 284 through a gate valve 260 and disposed below the chuck 250, opposite the first showerhead 225. The turbo molecular pumps 265, 266 may be any commercially available pumps having suitable throughput and more particularly may be sized appropriately to maintain process pressures below or about 5 Torr, 3 Torr, 1 Torr, 0.1 Torr 10 mTorr or below or about 5 mTorr at the desired flow rate of the first feed gas, e.g., 50 to 500 sccm of Ar where argon is the first feedgas. In the embodiment illustrated, the chuck 250 may form part of a pedestal which is centered between the two turbo pumps 265 and 266, however in alternate configurations chuck 250 may be on a pedestal cantilevered from the chamber wall 240 with a single turbo molecular pump having a center aligned with a center of the chuck 250.

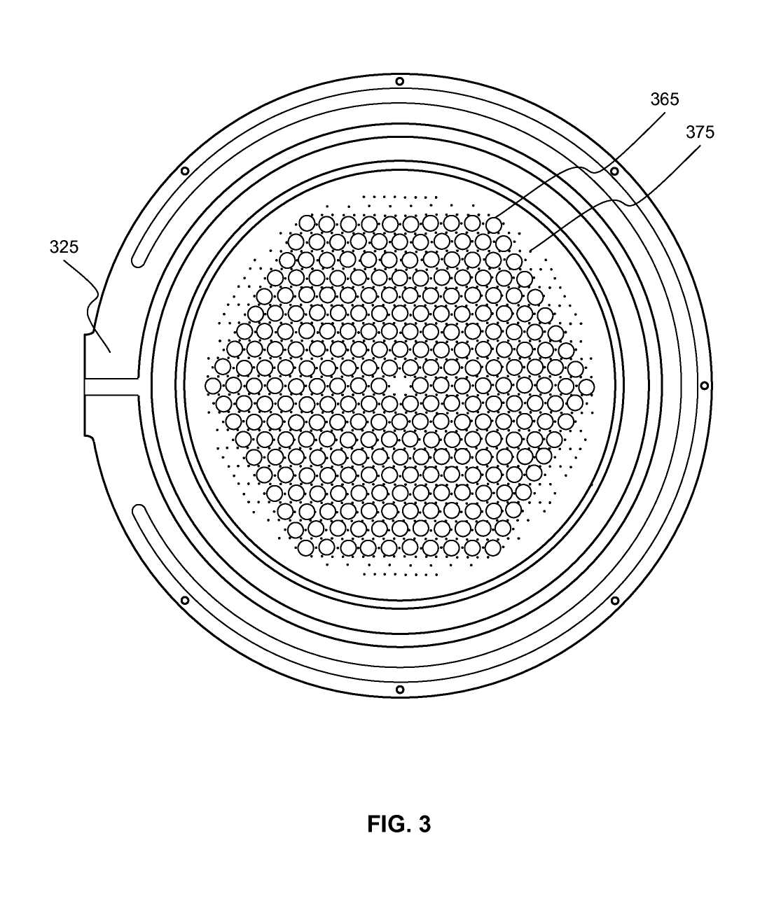

Disposed above the first showerhead 225 may be a second showerhead 210. In one embodiment, during processing, the first feed gas source, for example, Argon delivered from gas distribution system 290 may be coupled to a gas inlet 276, and the first feed gas flowed through a plurality of apertures 280 extending through second showerhead 210, into the second chamber region 281, and through a plurality of apertures 282 extending through the first showerhead 225 into the first chamber region 284. An additional flow distributor 215 having apertures 278 may further distribute a first feed gas flow 216 across the diameter of the etch chamber 200 through a distribution region 218. In an alternate embodiment, the first feed gas may be flowed directly into the first chamber region 284 via apertures 283 which are isolated from the second chamber region 281 as denoted by dashed line 223. For example, where the first showerhead is a dual-channel showerhead as previously described, the apertures 283 correspond to apertures 375 in FIG. 3. The process may be performed at low pressure, and may be performed at or below about 10 Torr, or below or about 5 Torr, 3 Torr, 1 Torr, 0.5 Torr, 0.1 Torr, 50 mTorr, 10 mTorr, 5 mTorr, 1 mTorr, etc., or less.

Chamber 200 may additionally be reconfigured from the state illustrated to perform an etching operation. A secondary electrode 205 may be disposed above the first showerhead 225 with a second chamber region 281 there between. The secondary electrode 205 may further form a lid of the etch chamber 200. The secondary electrode 205 and the first showerhead 225 may be electrically isolated by a dielectric ring 220 and form a second RF coupled electrode pair to capacitively discharge a second plasma 292 of a second feed gas within the second chamber region 281. Advantageously, the second plasma 292 may not provide a significant RF bias potential on the chuck 250. At least one electrode of the second RF coupled electrode pair is coupled to an RF source for energizing an etching plasma. The secondary electrode 205 may be electrically coupled with the second showerhead 210. In an exemplary embodiment, the first showerhead 225 may be coupled with a ground plane or floating and may be coupled to ground through a relay 227 allowing the first showerhead 225 to also be powered by the RF power source 228 during the ion milling mode of operation. Where the first showerhead 225 is grounded, an RF power source 208, having one or more RF generators operating at 13.56 MHz or 60 MHz for example may be coupled with the secondary electrode 205 through a relay 207 which will allow the secondary electrode 205 to also be grounded during other operational modes, such as during an ion milling operation, although the secondary electrode 205 may also be left floating if the first showerhead 225 is powered.

A second feed gas source, such as nitrogen trifluoride, and a hydrogen source, such as ammonia, may be delivered from gas distribution system 290, and coupled to the gas inlet 276 such as via dashed line 224. In this mode, the second feed gas may flow through the second showerhead 210 and may be energized in the second chamber region 281. Reactive species may then pass into the first chamber region 284 to react with the substrate 202. During such an operation, the process may be performed at higher pressures than the previously described operation. For example, the etching operation may be performed at process pressures at or above about 0.01 Torr, and may be performed at or above about 0.1 Torr, 0.5 Torr, 1 Torr, 2, Torr, 3 Torr, 4 Torr, 5 Torr, 6 Torr, 7 Torr, 8 Torr, 9 Torr, 10 Torr, 15 Torr, 20 Torr, etc., or higher. As further illustrated, for embodiments where the first showerhead 225 is a dual-channel showerhead, one or more feed gases may be provided to react with the reactive species generated by the second plasma 292. In one such embodiment, a water vapor source or other gaseous source may be coupled to the plurality of apertures 283.

In an embodiment, the chuck 250 may be movable along the distance H2 in a direction normal to the first showerhead 225. The chuck 250 may be on an actuated mechanism surrounded by a bellows 255, or the like, to allow the chuck 250 to move closer to or farther away from the first showerhead 225 as a means of controlling heat transfer between the chuck 250 and the first showerhead 225, which may be at an elevated temperature of 80° C.-150° C., or more. As such, an etch process may be implemented by moving the chuck 250 between first and second predetermined positions relative to the first showerhead 225. Alternatively, the chuck 250 may include a lifter 251 to elevate the substrate 202 off a top surface of the chuck 250 by distance H1 to control heating by the first showerhead 225 during the etch process. In other embodiments, where the etch process is performed at a fixed temperature such as about 90-110° C. for example, chuck displacement mechanisms may be avoided. A system controller may alternately energize the first and second plasmas 270 and 292 during the etching process by alternately powering the first and second RF coupled electrode pairs automatically.

The chamber 200 may also be reconfigured to perform a deposition operation. A plasma 292 may be generated in the second chamber region 281 by an RF discharge which may be implemented in any of the manners described for the second plasma 292. Where the first showerhead 225 is powered to generate the plasma 292 during a deposition, the first showerhead 225 may be isolated from a grounded chamber wall 240 by a dielectric spacer 230 so as to be electrically floating relative to the chamber wall. In the exemplary embodiment, an oxidizer feed gas source, such as molecular oxygen, may be delivered from gas distribution system 290, and coupled to the gas inlet 276. In embodiments where the first showerhead 225 is a dual-channel showerhead, any silicon-containing precursor, such as OMCTS may be delivered from gas distribution system 290, and coupled into the first chamber region 284 to react with reactive species passing through the first showerhead 225 from the plasma 292. Alternatively the silicon-containing precursor may also be flowed through the gas inlet 276 along with the oxidizer.

Chamber 200 may be used for a number of etching and deposition processes, for example. Additional examples of etching and deposition processes and chambers that may be used in conjunction with the disclosed technology and chamber 200 are described in co-assigned application Ser. No. 13/651,074 titled “Process chamber for Etching Low K and Other Dielectric Films,” and filed Oct. 12, 2012, the entire contents of which are hereby incorporated by reference for all purposes not inconsistent with the present disclosure.

FIG. 3 shows a bottom plan view of a showerhead according to the disclosed technology. Showerhead 325 may correspond with the showerhead 225 shown in FIG. 2. Through-holes 365, which show a view of first fluid channels 282 for example, may have a plurality of shapes and configurations in order to control and affect the flow of precursors through the showerhead 325. For example, the apertures may make any geometrical pattern in their arrangement as may affect fluid distribution, and may be distributed as rings of apertures located concentrically outward from each other and based on a centrally located position on the plate. As one example, and without limiting the scope of the technology, FIG. 3 shows a pattern formed by the apertures that includes concentric hexagonal rings extending outwardly from the center. Each outwardly located ring may have the same number, more, or less apertures than the preceding ring located inwardly. In one example, each concentric ring may have an additional number of apertures based on the geometric shape of each ring. In the example of a six-sided polygon, each ring moving outwardly may have six apertures more than the ring located directly inward, with the first internal ring having six apertures. With a first ring of apertures located nearest to the center of the plate, the plate or plates may have more than two rings, and depending on the geometric pattern of apertures used, may have between about one and about fifty rings of apertures. In one example, as shown, there may be nine hexagonal rings on the exemplary plate.

The concentric rings of apertures may also not have one of the concentric rings of apertures, or may have one of the rings of apertures extending outward removed from between other rings. For example with reference to FIG. 3, where an exemplary nine hexagonal rings are on the plate, the plate may instead have eight rings, but it may be ring four that is removed. In such an example, channels may not be formed where the fourth ring would otherwise be located which may redistribute the gas flow of a fluid being passed through the apertures. The rings may still also have certain apertures removed from the geometric pattern. For example again with reference to FIG. 3, a tenth hexagonal ring of apertures may be formed on the plate shown as the outermost ring. However, the ring may not include apertures that would form the vertices of the hexagonal pattern, or other apertures within the ring. Small holes 375, which show a view of second fluid channels delivering fluids through path 283 for example, may be distributed substantially evenly over the surface of the showerhead, even amongst the through-holes 365, which may help to provide more even mixing of the precursors as they exit the showerhead than other configurations.

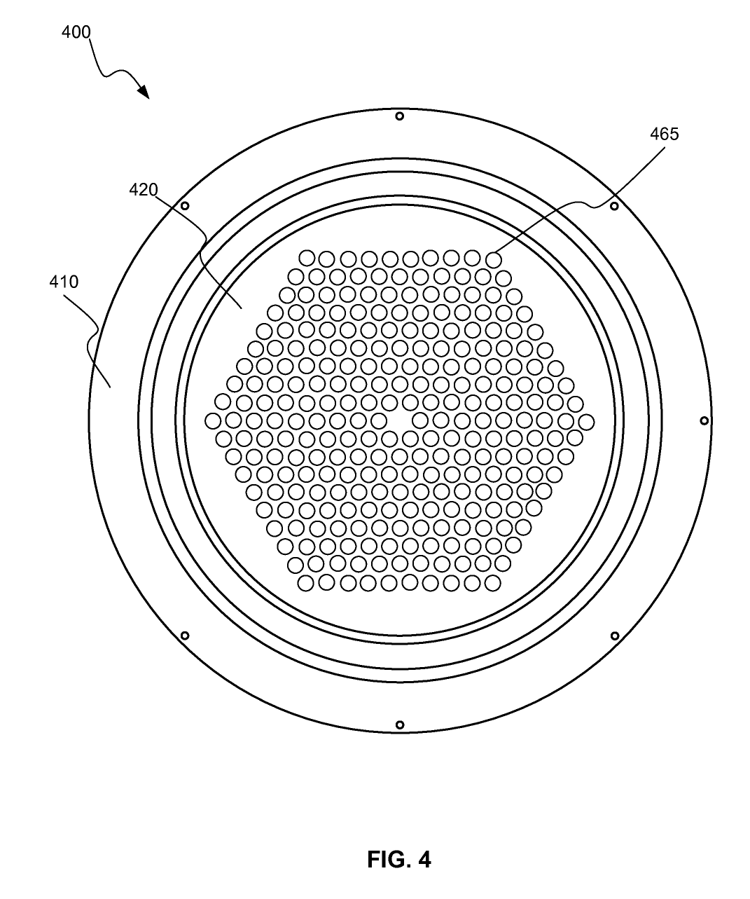

An alternative arrangement for a showerhead or faceplate according to disclosed embodiments is illustrated in FIG. 4, which shows a bottom plan view of another showerhead according to the disclosed technology. As shown, the showerhead 400 may comprise a perforated plate or manifold. The assembly of the showerhead may be similar to the showerhead as shown in FIG. 3, or may include a design configured specifically for distribution patterns of precursor gases, such as through second showerhead 210 as discussed above with respect to FIG. 2. Showerhead 400 may include an annular frame 410 positioned in various arrangements within an exemplary processing chamber, such as one or more arrangements as shown in FIG. 2. On or within the frame may be coupled a plate 420, which may be similar in disclosed embodiments to plate 320 as previously described. The plate may have a disc shape and be seated on or within the frame 410. The plate may be of a variety of thicknesses, and may include a plurality of apertures 465 defined within the plate. An exemplary arrangement as shown in FIG. 4 may include a pattern as previously described with reference to the arrangement in FIG. 3, and may include a series of rings of apertures in a geometric pattern, such as a hexagon as shown. As would be understood, the pattern illustrated is exemplary and it is to be understood that a variety of patterns, hole arrangements, and hole spacing are encompassed in the design. Alternatively, showerhead 400 may be a single plate design and compose a single-piece construction.

As discussed above with respect to chamber 200, the system may be used to perform operations and very low pressures, as well as higher pressures. For example, processes as described previously may be performed in sequence or during the same overall processing step within the chamber 200 in order to perform a multi-step etching operation. For example, the first process described above may be performed to modify a material disposed on a semiconductor substrate. Such a modification may be performed at low pressure to provide directionality to an ion bombardment or delivery. As pressure increases, the mean free path of the formed ions may decrease, which may cause unwanted ion collisions within a formed sheath region of the plasma. Although in certain processes ion collisions may be acceptable, under other processes, by reducing ion collisions, improved control may be afforded to the directionality of delivered ions to reduce the angular spread of ions impinging the wafer. As such, low or very low pressures may be utilized to maintain directionality of the ions.

A subsequent portion of the multi-step etching operation, such as the etching operation discussed above, may benefit from increased pressures over the first ion-based operation. For example, with an ammonia-based treatment as previously described, increased pressures may increase the dissociation of the precursors utilized in the process, which may allow improved etching. Additionally, the components produced in the plasma may include both more and less desired components. Higher pressures may benefit certain components, such as NH₄F, for example, while less desirable components in certain etching operations such as fluorine radicals, may be more likely to recombine at high pressures allowing improved selectivity of the operation. Conventional systems may have required multiple chambers to be employed in order to perform the subsequent processes because of the differing pressure schemes, however, chamber 200 may be configured to perform both operations as will be discussed in further detail below.

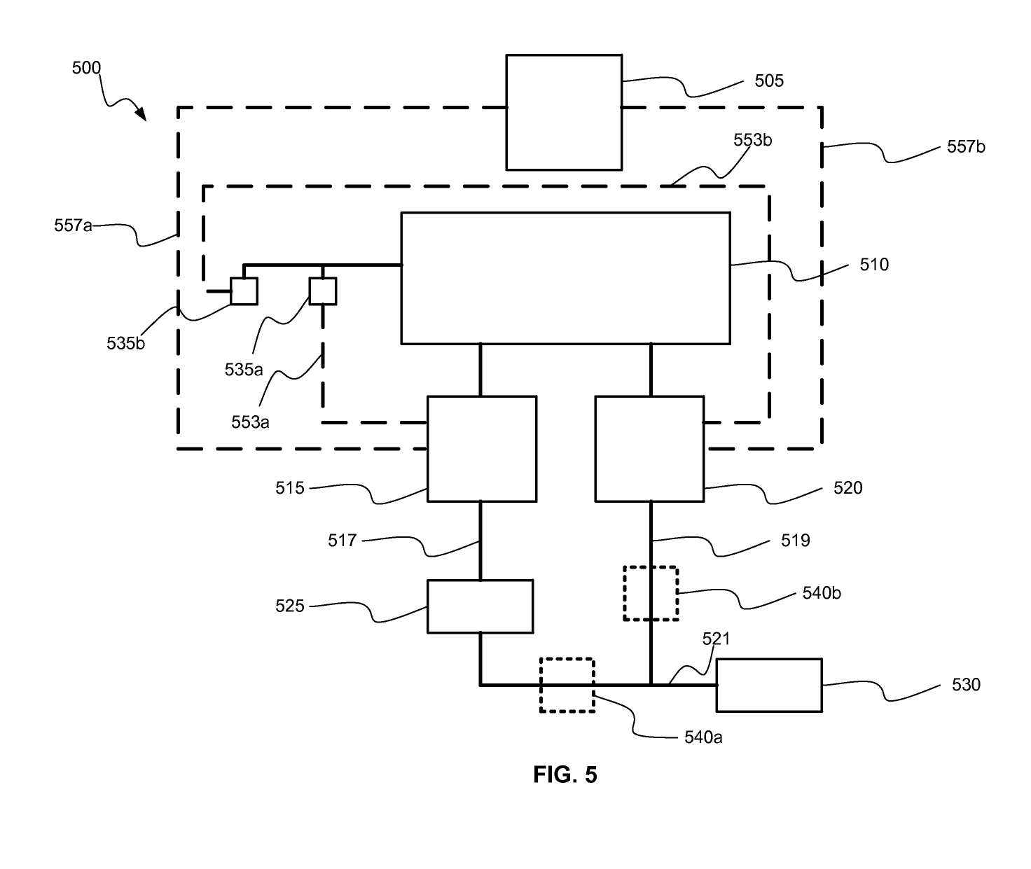

Turning to FIG. 5 is shown a simplified schematic of system 500 according to the disclosed technology that may allow precise system control at multiple pressure ranges. The system may include a processing chamber 510, and a first pressure regulating device 515 coupled with the processing chamber. The system may include a second pressure regulating device 520 coupled with the processing chamber separately from the first pressure regulating device 515. The system may further include a first pump 525 coupled with the first pressure regulating device 515 and fluidly isolated from the second pressure regulating device 520. The system may also include a second pump 530 fluidly coupled with the second pressure regulating device 520. The system may include optional valves 540 configured to isolate the first pressure regulating device 515 and second pressure regulating device 520 from the second pump 530 during operation.

The first pressure regulating device 515 and second pressure regulating device 520 may be similar devices in disclosed embodiments and may both be valves or fluid throttling devices. The valves may be gate valves, isolation valves, butterfly valves, globe valves, ball valves, or any other device capable of being controlled to regulate fluid flow across the device. The pressure regulating devices may be hydraulic, pneumatic, manual, solenoid, or motor driven, and may or may not include an actuator in the configuration, and may be made of a variety of materials as would be understood by the skilled artisan. The pressure regulating devices may be sized similarly, or may be sized differently so as to allow separate operation at multiple pressure regimes. For example, first pressure regulating device 515 may be sized and/or configured to regulate the processing chamber pressure within a first pressure range, which may be above, at, or below about 5 Torr in disclosed embodiments, and may be sized to operate or regulate the processing chamber at or below about 3 Torr, 1 Torr, 0.5 Torr, 0.1 Torr, 10 mTorr, 5 mTorr, 1 mTorr, etc. or below, or may be sized to operate or regulate within a range of any of these stated pressures. For example, the first pressure regulating device 515 may be sized to operate in a range of from about 3 Torr or below to about or below 1 mTorr, or from about 1 Torr to about 5 mTorr or below.

The second pressure regulating device 520 may be similar to the first pressure regulating device, or may be a different valve type, size, or construction in disclosed embodiments. For example, the second pressure regulating device 520 may be sized and/or configured to regulate the processing chamber pressure within a second pressure range, which may be above, at, or below about 0.1 Torr in disclosed embodiments, and may be sized to operate or regulate the processing chamber at or above about 0.5 Torr, 1 Torr, 2 Torr, 3 Torr, 4 Torr, 5 Torr, 6 Torr, 7 Torr, 8 Torr, 9 Torr, 10 Torr, 15 Torr, 20 Torr, etc. or above, or may be sized to operate or regulate within a range of any of these stated pressures.

The first pressure regulating device 515 and second pressure regulating device 520 may be operated in conjunction or operated distinctly with system controller 505, for example. In disclosed embodiments the first pressure regulating device 515 and second pressure regulating device 520 are provided operational setpoints with system controller 505, and then operated to affect the system or chamber pressure to provide the setpoint pressure. The pressure regulating devices may be operated to work in tandem such that a broader overall pressure regime may be provided with improved control. For example, the first pressure regulating device may be configured to be closed when the second pressure regulating device is open, and the second pressure regulating device may be configured to be closed when the first pressure regulating device is open. In this way, the devices may operate as crossover controllers to provide a greater range of control based on designated device sizing. For example, if the first pressure regulating device 515 is sized to regulate chamber pressure from about 0.1 mTorr or above to about 3 Torr or below, and the second pressure regulating device is sized to regulate chamber pressure from about 0.1 Torr or above to about 20 Torr or above, the system may provide chamber pressure control from between about 0.1 mTorr up to about 20 Torr, for example, by operating the regulating devices in conjunction. Because pumps, valves, fittings, etc., may be sized or selected based on a higher or lower operating pressure, the changeover design may allow greater flexibility without possibly damaging sensitive equipment that is sized to operate in a more limited range.

The processing system may also include one or more pressure measuring devices coupled with the processing chamber, such as pressure measuring devices 535, to provide feedback by which the pressure regulating devices may adjust the chamber pressure conditions. As illustrated in FIG. 5, the system may include at least one first pressure measuring device 535a coupled with the processing chamber and configured to provide information to the first pressure regulating device 515. The system may also include at least one second pressure measuring device 535b coupled with the processing chamber and configured to provide information to the second pressure regulating device 520. The total number of pressure measuring devices 535 may be at least 1, 2, 3, 4, 5, 6, etc. or more, and may be based on the overall pressure scheme utilized by the chamber, or the sensitivity of control required for the operations performed within the chamber. For example, the system may include at least three pressure measuring devices 535 sized at three different control conditions, such as up to about 0.1 Torr, up to about 1 Torr, and/or up to about 10 Torr, to provide feedback capability at a variety of conditions. One or more of each pressure measuring device 535 may be coupled with each pressure regulating device 515, 520 in order to provide feedback at different pressure ranges.

First pump 525 and second pump 530 may be of similar design or size and may be selected based on a variety of operational and performance characteristics. Each pump may be positive displacement, direct lift, or gravity fed, and may be a turbomolecular pump or other mechanical pump in disclosed embodiments. For example, first pump 525 may be a turbomolecular pump such as previously described, and second pump 530 may be a mechanical pump sized for a higher pressure. Accordingly, when a low pressure operation is used, second pump 530 may more quickly reduce the pressure of the chamber below a threshold pressure, and second pump 525 may then reduce the pressure to the determined operating condition. As such, first pump 525 in operation with first pressure regulating device 515 may regulate the pressure of the chamber during low pressure operation, and second pump 530 in operation with second pressure regulating device 520 may regulate the pressure of the chamber during higher pressure operation, for example.

The components may be coupled in a variety of ways, and FIG. 5 illustrates a single disclosed embodiment. It is to be understood that a variety of piping schemes may be used, and various other components not shown, including valves various rough-in lines and other piping components may be included. For example, the semiconductor processing system may include a processing chamber 510 as shown, and a first pressure regulating device 515 coupled with the processing chamber along a first fluid line 517. The system may also include a second pressure regulating device 520 coupled with the processing chamber separately from the first pressure regulating device 515 along a second fluid line 519. A first pump 525 may be fluidly coupled with the first pressure regulating device 515 along the first fluid line 517, and a second pump 530 may be coupled with the second pressure regulating device 520. As discussed previously, the system may include at least one first pressure measuring device 535a coupled with the processing chamber and configured to provide information to the first pressure regulating device 515, as well as at least one second pressure measuring device 535b coupled with the processing chamber and configured to provide information to the second pressure regulating device 520. For example, the system may include two first pressure measuring devices 535a coupled with the processing chamber and coupled with the first pressure regulating device 515 to provide feedback information to the first pressure regulating device 515.

The second pump 530 may also be fluidly coupled with the first pressure regulating device 525. The second pump may be coupled with a third fluid line 521 that is fluidly coupled with both the first fluid line 517 and second fluid line 519. Optional components 540 may include isolation valves that allow the first fluid line 517 and second fluid line 519 to be fluidly isolated during operation of the second pump 530.

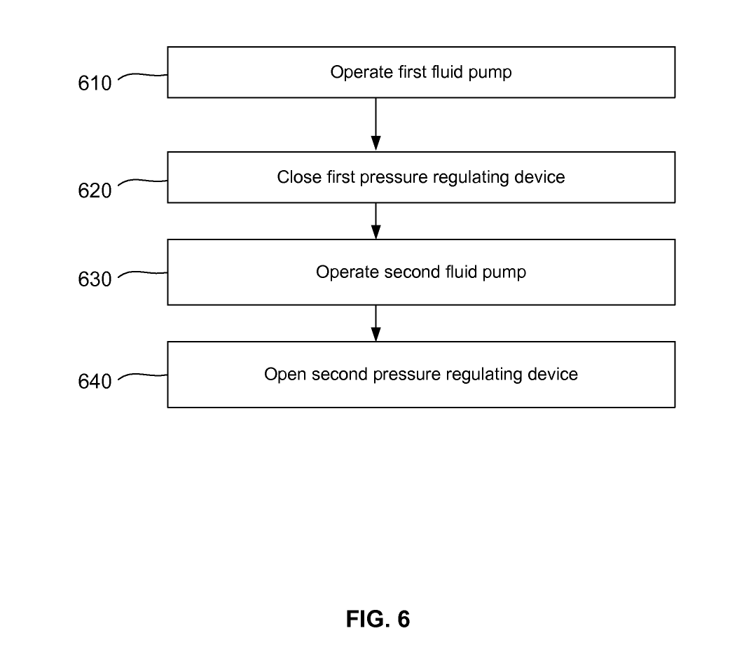

FIG. 6 illustrates methods of operating a semiconductor processing system according to the disclosed technology, and may allow for multiple process operations to be performed within the chamber without removing the substrate from the chamber environment. A substrate may be delivered to a semiconductor processing chamber, and the substrate may have been previously patterned, and previous deposition, etching, and curing operations may have been performed. Within the chamber one or more deposition operations may be performed, or a multi-step etching operation may be performed upon the delivery of the substrate. The method may include operating a first fluid pump at operation 610, where the pump is coupled with a semiconductor processing chamber with a first pressure regulating device. The operation may produce a processing chamber pressure within a first pressure range. The method may include closing the first pressure regulating device at operation 620, and then operating a second fluid pump at operation 630. The second fluid pump may also be coupled with the semiconductor processing chamber with a second pressure regulating device. The method may further include opening a second pressure regulating device at operation 640 to produce a processing chamber pressure within a second pressure range.

The first and second pressure ranges may be similar or different from one another, and in disclosed embodiments, the first pressure range may be higher than the second pressure range. Any of the previously discussed pressures and/or ranges may be encompassed by the method, and in disclosed embodiments the first pressure range may be at or above about 1 Torr, and the second pressure range may be at or below about 1 Torr, for example. Such a configuration may allow initial control at a first higher pressure utilizing the first pressure regulating device followed by subsequent operation at a lower pressure regime utilizing a second pressure regulating device. In this way, the separate pressure regulating devices may precisely control the operational pressure within the chamber.

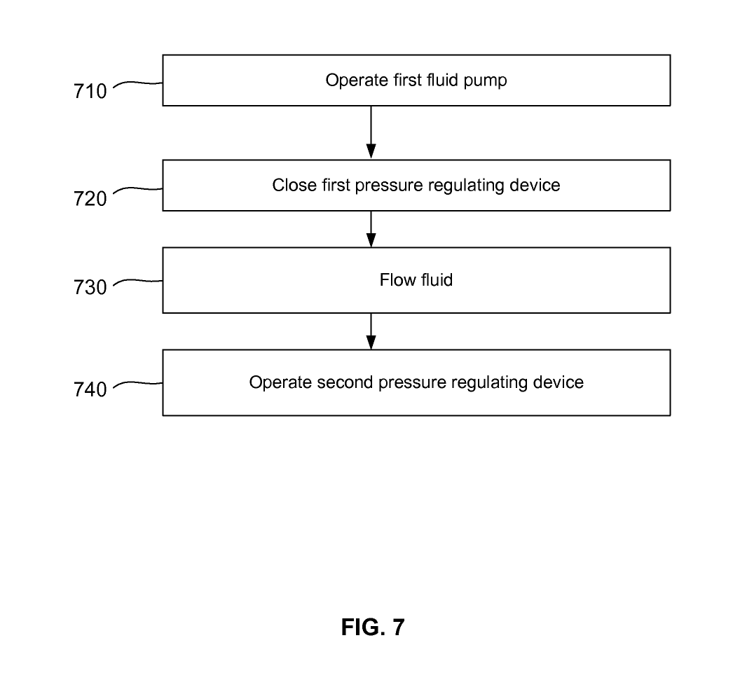

FIG. 7 illustrates additional methods of operating a semiconductor processing system according to the disclosed technology. The method may include operating a first fluid pump coupled with a semiconductor processing chamber with a first pressure regulating device at operation 710 to produce a processing chamber pressure within a first pressure range. The methods may also include closing the first pressure regulating device at operation 720, and flowing a fluid into the processing chamber at operation 730. The methods may further include operating a second pressure regulating device coupled with the semiconductor processing chamber at operation 740 to regulate the processing chamber within a second pressure range.

Such methods may allow a multi-step etching operation to be performed in which the steps occur at different pressures. For example, the first etching step may include utilizing an ion bombardment to modify a surface of a material. Such a process may benefit from a relatively low or very low process pressure, such as below about 1 Torr, or below about 0.1 Torr, for example. A second portion of the multi-step etch may include interacting precursors such as previously described with the surface of a substrate, which may be performed at a higher pressure to increase precursor dissociation. Such a process may be performed above about 0.1 Torr, or above about 1 Torr, for example. As such, the first pressure range may be at or below about 1 Torr, and the second pressure range may be at or above about 1 Torr.

When performing an operation at a lower pressure and then preparing for an operation at a higher pressure, the system may be pressurized or repressurized in a variety of ways. For example, one or more process gases that are being flowed through the system may allow the chamber to pressurize to a predetermined operating pressure. The fluids may include inert fluids or a variety of process precursors used in the various operations. For example, after the first pressure regulating device has closed, but prior to opening the second pressure regulating device, one or more fluids may be flowed into the processing chamber in order to pressurize the vessel. Depending on the level of pressurization required, the time between closing the first pressure regulating device and opening the second pressure regulating device may be adjusted accordingly, and regulated by one or more pressure measuring devices coupled with the processing chamber. Additionally, the fluid or fluids may be continuously flowed during the operations, and are maintained flowing while the regulating devices are switched over and the system pressurizes.

Although in certain configurations a single pressure regulating device may be used within the system for the processes described, such a device may not provide adequate precision within both pressure ranges. For example, if the first pressure range is between about 0 and 0.1 Torr, and the second pressure range is between about 2 and 10 Torr, a single pressure regulating device may not provide the same quality of control as two separate pressure regulating devices sized at the separate operating ranges. Additionally, one or more of the pumps utilized in the configuration may not be suitable across the entire range, and may be damaged or unable to properly perform at either of the pressure ranges. Accordingly, the pumps and pressure regulating devices may be coupled with the processing chamber in order to allow precise control at two or more pressure ranges, while protecting the pumps and devices coupled with the system.

The system may also include one or more pressure measuring devices that provide pressure information to one or more of the pressure regulating devices. The system may include multiple pressure measuring devices configured to provide precise pressure measurements within the chamber at a variety of operating pressures. For example, pressure measurement devices may include a first device that measures at or below about 0.1 Torr and a second device that measures at or below about 10 Torr. By having narrower operating ranges, more precise pressure measurements may be afforded for improved control by the pressure regulating devices.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the disclosed embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “an aperture” includes a plurality of such apertures, and reference to “the fluid line” includes reference to one or more fluid lines and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or steps, but they do not preclude the presence or addition of one or more other features, integers, components, steps, acts, or groups.

What is claimed is:

1. A semiconductor processing system comprising:
a processing chamber;
a first pressure regulating device coupled with the processing chamber;
a second pressure regulating device coupled with the processing chamber separately from the first pressure regulating device;
a first pump fluidly coupled with the first pressure regulating device and fluidly isolated from the second pressure regulating device; and
a second pump fluidly coupled with the second pressure regulating device.

2. The semiconductor processing system of claim 1, further comprising:
at least one first pressure measuring device coupled with the processing chamber and configured to provide information to the first pressure regulating device.

3. The semiconductor processing system of claim 2, further comprising:
at least one second pressure measuring device coupled with the processing chamber and configured to provide information to the second pressure regulating device.

4. The semiconductor processing system of claim 1, wherein the first pressure regulating device is configured to regulate the processing chamber pressure within a first pressure range.

5. The semiconductor processing system of claim 4, wherein the first pressure range is at or below about 5 Torr.

6. The semiconductor processing system of claim 5, wherein wherein the first pressure range is at or below about 1 Torr.

7. The semiconductor processing system of claim 1, wherein the second pressure regulating device is configured to regulate the processing chamber pressure within a second pressure range.

8. The semiconductor processing system of claim 7, wherein the second pressure range is at or above about 0.1 Torr.

9. The semiconductor processing system of claim 8, wherein the second pressure range is at or above about 1 Torr.

10. The semiconductor processing system of claim 1, wherein the second pressure regulating device is configured to be closed when the first pressure regulating device is open.

11. The semiconductor processing system of claim 1, wherein the first pressure regulating device is configured to be closed when the second pressure regulating device is open.

12. A semiconductor processing system comprising:
a processing chamber;
a first pressure regulating device coupled with the processing chamber along a first fluid line;
a second pressure regulating device coupled with the processing chamber separately from the first pressure regulating device along a second fluid line;
a first pump fluidly coupled with the first pressure regulating device along the first fluid line; and
a second pump fluidly coupled with the second pressure regulating device.

13. The semiconductor processing system of claim 12, wherein the second pump is fluidly coupled with the first pressure regulating device.

14. The semiconductor processing system of claim 13, wherein the second pump is fluidly coupled with a third fluid line fluidly coupled with both the first fluid line and the second fluid line.

15. The semiconductor processing system of claim 12, further comprising:
at least one first pressure measuring device coupled with the processing chamber and configured to provide information to the first pressure regulating device.

16. The semiconductor processing system of claim 15, further comprising:
at least one second pressure measuring device coupled with the processing chamber and configured to provide information to the second pressure regulating device.

17. A method of operating a semiconductor processing system, the method comprising:
operating a first fluid pump coupled with a semiconductor processing chamber with a first pressure regulating device to produce a processing chamber pressure within a first pressure range;
closing the first pressure regulating device;
operating a second fluid pump coupled with the semiconductor processing chamber with a second pressure regulating device; and
opening the second pressure regulating device to produce a processing chamber pressure within a second pressure range.

18. The method of claim 17, wherein the first pressure range is at or above about 1 Torr, and the second pressure range is at or below about 1 Torr.

19. A method of operating a semiconductor processing system, the method comprising:
operating a first fluid pump coupled with a semiconductor processing chamber with a first pressure regulating device to produce a processing chamber pressure within a first pressure range;
closing the first pressure regulating device;
flowing a fluid into the processing chamber; and
operating a second pressure regulating device coupled with the semiconductor processing chamber to regulate the processing chamber within a second pressure range.

20. The method of claim 19, wherein the first pressure range is at or below about 1 Torr, and the second pressure range is at or above about 1 Torr.
